(19) United States
(12) Patent Application Publication
(10) Pub. No.: US 2024/0332407 A1
(43) Pub. Date: Oct. 3, 2024

(54) POWER SEMICONDUCTOR DEVICE INCLUDING A DIODE AREA

(71) Applicant: Infineon Technologies Austria AG, Villach (AT)

(72) Inventors: Matteo Dainese, München (DE); Natalie Charlotte Segercrantz, München (DE); Aleksander Hinz, Dresden (DE); Thomas Hunger, Dresden (DE); Christian Philipp Sandow, Haar (DE)

(21) Appl. No.: 18/610,463

(22) Filed: Mar. 20, 2024

(30) Foreign Application Priority Data
Mar. 29, 2023 (DE) 102023202872.7

(51) Int. Cl. H01L 29/739; H01L 27/06; H01L 27/07; H01L 29/06; H01L 29/66; H01L 29/861

(52) U.S. Cl. CPC H01L 29/7395; H01L 27/0664; H01L 27/0727; H01L 29/0696; H01L 29/66136; H01L 29/66333; H01L 29/8611

(57) ABSTRACT

A power semiconductor device is proposed. The power semiconductor device includes a semiconductor substrate having first and second main surfaces arranged opposite to each other. The semiconductor substrate includes an insulated gate bipolar transistor area (IGBT) area including an IGBT, and a diode area including a diode. The diode area includes a cathode region of a first conductivity type and an auxiliary region of a second conductivity type both adjoining to the second main surface of the semiconductor substrate. The cathode region adjoins to the auxiliary region along a first lateral direction. The IGBT area includes a collector region of the second conductivity type at the second main surface of the substrate. The collector region includes a first collector sub-region and a second collector sub-region adjoining to each other along the first lateral direction. The first collector sub-region has a larger maximum doping concentration than the second collector sub-region.

### TECHNICAL FIELD

The present disclosure relates to a power semiconductor device including a diode area, in particular to a power semiconductor device including an insulated gate bipolar transistor, IGBT area and the diode area, e.g. a reverse conducting IGBT (RC-IGBT) or to a diode including the diode area.

### BACKGROUND

Many functions of modern devices in automotive, consumer and industrial applications, such as converting electrical energy and driving an electric motor or an electric machine, rely on power semiconductor switches. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters. A power semiconductor device typically includes a semiconductor substrate configured to conduct a forward load current along a load current path between two load terminals of the device. Further, in case of a controllable power semiconductor device, e.g., a transistor, the load current path may be controlled by means of an insulated electrode, commonly referred to as gate electrode. For example, upon receiving a corresponding control signal from, e.g., a driver unit, the control electrode may set the power semiconductor device in one of a conducting state and a blocking state.

Some power semiconductor devices further provide for a reverse conductivity. During a reverse conducting state, the power semiconductor device conducts a reverse load current. Such devices may be designed such that the forward load current capability (in terms of magnitude) is substantially the same as the reverse load current capability.

A typical device that provides for both forward and reverse load current capability is the RC-IGBT, the general configuration of which is known to the skilled person. Typically, for an RC-IGBT, the forward conducting state is controllable by means of providing a corresponding signal to the gate electrodes, and the reverse conducting state is typically not controllable, but the RC-IGBT assumes the reverse conducting state if a reverse voltage is present at the load terminals due to a corresponding diode area in the RC-IGBT.

It is desirable to provide a power semiconductor device, e.g. a power RC-IGBT or a power semiconductor diode, with a high degree of controllability and robustness in addition to a high efficiency in terms of power losses.

### SUMMARY

An example of the present disclosure relates to a power semiconductor device. The power semiconductor device includes a semiconductor substrate having a first main surface and a second main surface arranged opposite to each other. The semiconductor substrate includes an insulated gate bipolar transistor area, IGBT area, comprising an IGBT, and a diode area comprising a diode. The diode area includes a cathode region of a first conductivity type at the second main surface of the semiconductor substrate, and an auxiliary region of a second conductivity type at the second main surface of the semiconductor substrate. The cathode region adjoins to the auxiliary region along a first lateral direction. The IGBT area includes a collector region of the second conductivity type at the second main surface of the semiconductor substrate. The collector region includes a first collector sub-region and a second collector sub-region adjoining to each other along the first lateral direction. The first collector sub-region has a larger maximum doping concentration than the second collector sub-region.

A further example of the present disclosure relates to another power semiconductor device. The power semiconductor device includes a semiconductor substrate having a first main surface and a second main surface arranged opposite to each other. The semiconductor substrate includes a diode area comprising a diode. The diode area includes a cathode region of a first conductivity type at the second main surface of the semiconductor substrate, and an auxiliary region of a second conductivity type at the second main surface of the semiconductor substrate. The cathode region adjoins to the auxiliary region along a first lateral direction. The doping concentration of the auxiliary region varies along the first lateral direction.

Another example of the present disclosure relates to a method of manufacturing a power semiconductor device. The method includes providing a semiconductor substrate having a first main surface and a second main surface arranged opposite to each other. The method further includes forming an IGBT in an insulated gate bipolar transistor area, IGBT area, and a diode in a diode area. Forming the diode in the diode area includes forming a cathode region of a first conductivity type at the second main surface of the semiconductor substrate, and an auxiliary region of a second conductivity type at the second main surface of the semiconductor substrate. The cathode region adjoins to the auxiliary region along a first lateral direction. Forming the IGBT in the IGBT area includes forming a collector region of the second conductivity type at the second main surface of the semiconductor substrate. The collector region includes a first collector sub-region and a second collector sub-region adjoining to each other along the first lateral direction. The first collector sub-region has a larger maximum doping concentration than the second collector sub-region.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of power semiconductor devices and together with the description serve to explain principles of the examples. Further examples are described in the following detailed description and the claims.

FIGS. 1 and 2 are schematic cross-sectional views for illustrating examples of power semiconductor devices including an IGBT area and a diode area.

FIG. 3 is a schematic top view for illustrating an exemplary layout of a power semiconductor device including diode areas embedded into an IGBT area.

FIGS. 4 to 8 are schematic top views for illustrating exemplary layouts of cathode regions and auxiliary regions in the diode area of a power semiconductor device.

FIGS. 9A to 10 are schematic top views for illustrating exemplary layouts of first and second collector sub-region in the IGBT area of a power semiconductor device.

FIGS. 11A and 11B illustrate exemplary doping concentration profiles in the auxiliary region of the diode area of a power semiconductor device.

FIGS. 12A and 12B are schematic cross-sectional views for illustrating different mask layouts for forming a varying lateral doping concentration profile in the auxiliary region of the diode area of a power semiconductor device.

FIG. 13 is a schematic top view for illustrating a power semiconductor device including an interface region separating a diode area from an edge termination area.

FIGS. 14A to 14C are schematic cross-sectional views for illustrating process features of manufacturing a power semiconductor device.

### DETAILED DESCRIPTION

In the following detailed description, reference is made to the accompanying drawings, which form a part hereof and in which are shown by way of illustrations specific examples in which power semiconductor devices may be formed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact may be a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a power semiconductor device. The power semiconductor device includes a semiconductor substrate having a first main surface and a second main surface arranged opposite to each other. The semiconductor substrate may include an insulated gate bipolar transistor area, IGBT area, comprising an IGBT, and a diode area comprising a diode. The diode area may include a cathode region of a first conductivity type at the second main surface of the semiconductor substrate, and an auxiliary region of a second conductivity type at the second main surface of the semiconductor substrate. The cathode region may adjoin to the auxiliary region along a first lateral direction. The IGBT area may include a collector region of the second conductivity type at the second main surface of the semiconductor substrate. The collector region may include a first collector sub-region and a second collector sub-region adjoining to each other along the first lateral direction. The first collector sub-region may have a larger maximum doping concentration than the second collector sub-region.

The power semiconductor device may be part of an integrated circuit or may be a discrete semiconductor device or a semiconductor module, for example. The power semiconductor device may be or may include a vertical power semiconductor device having a load current flow between the first main surface and the second main surface. The power semiconductor device may be or may include a power semiconductor RC-IGBT or a power semiconductor diode. The power semiconductor device may be configured to conduct currents of more than 1 A or more than 10 A or even more than 30 A, and may be further configured to block voltages between load terminals, e.g. between collector and emitter or between cathode and anode, in the range of several hundreds of up to several thousands of volts, e.g. 400 V, 650V, 1.2 kV, 1.7 kV, 3.3 kV, 4.5 kV, 5.5 kV, 6 kV, 6.5 kV. The blocking voltage may correspond to a voltage class specified in a datasheet of the power semiconductor device, for example.

The semiconductor substrate may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). For example, the semiconductor substrate may be formed of a base substrate, e.g. wafer, having none, one or even more semiconductor layers such as epitaxial semiconductor layers on the base substrate. The semiconductor substrate may be a Czochralski (CZ), e.g. a magnetic Czochralski (MCZ) or a float zone (FZ), or an epitaxially deposited silicon semiconductor substrate.

The first main surface may be a front surface or a top surface of the power semiconductor device, and the second main surface may be a back surface or a rear surface of the power semiconductor device, for example. The semiconductor substrate may be attached to a lead frame via the second main surface, for example. Over the first main surface of the semiconductor substrate, bond pads may be arranged and bond wires may be bonded on the bond pads.

For realizing a desired current carrying capacity, the power semiconductor device may be designed by a plurality of parallel-connected IGBT and/or diode cells. The parallel-connected IGBT and/or diode cells may, for example, be IGBT and/or diode cells formed in the shape of a stripe or a stripe segment. The IGBT and/or diode cells can also have any other shape, e.g. circular, elliptical, polygonal such as hexagonal or octahedral. For example, the IGBT cells may be arranged in the IGBT area, and the diode cells may be arranged in the diode area. The IGBT and/or diode cells may be arranged in an active area of the power semiconductor device. The active area may be defined by an area of the semiconductor substrate where an emitter region of the IGBT cells at the first main surface and a collector region of the IGBT cells at the second main surface are arranged opposite to one another along the vertical direction. The active area may also include an area of the semiconductor body where an anode region of the diode cells at the first main surface and a cathode region of the diode cells at the second main surface are arranged opposite to one another along the vertical direction. In the active area, a load current may enter or exit the semiconductor substrate of the power semiconductor device, e.g. via contact plugs on the first main surface of the semiconductor substrate. For example, the active area may be defined by an area where contact plugs are placed over the first main surface for electrically connecting an electrode over the first main surface to semiconductor layers in the IGBT or diode area.

The power semiconductor device may also include an edge termination area that may include a termination structure. In a blocking mode or in a reverse biased mode of the power semiconductor device, the blocking voltage between the transistor cell area or the diode cell area and a field-free region laterally drops across the termination structure in the edge termination area. The termination structure may have a higher or a slightly lower voltage blocking capability than the transistor cell area or the diode cell area. The termination structure may include a junction termination extension (JTE) with or without a variation of lateral doping (VLD), one or more laterally separated guard rings, or any combination thereof, for example.

The blocking voltage of the power RC-IGBT or diode may be adjusted along a vertical direction perpendicular to the first main surface by adjusting parameters of a drift region, e.g. vertical extent and/or doping profile. An impurity or doping concentration in the drift region may gradually or in steps increase or decrease with increasing distance to the first main surface at least in portions of its vertical extension. According to other examples the impurity concentration in the drift region may be approximately uniform in the vertical direction. For RC-IGBTs based on silicon, a mean impurity concentration in the drift region may be between 5×10¹² cm⁻³ and 1×10¹⁵ cm⁻³, for example in a range from 1×10¹³ cm⁻³ to 2×10¹⁴ cm⁻³. In the case of an RC-IGBT based on SiC, a mean impurity concentration in the drift region may be between 5×10¹⁴ cm⁻³ and 1×10¹⁷ cm⁻³, for example in a range from 1×10¹⁵ cm⁻³ to 2×10¹⁶ cm⁻³. A vertical extension of the drift region may depend on voltage blocking requirements, e.g. a specified voltage class, of the power semiconductor device. When operating the power semiconductor device in voltage blocking mode, a space charge region may vertically extend partly or totally through the drift region depending on the blocking voltage applied to the vertical power semiconductor device. When operating the vertical power semiconductor device at or close to the specified maximum blocking voltage, the space charge region may reach or penetrate into a field stop region. The field stop region is configured to prevent the space charge region from further reaching to the cathode or collector at the second main surface of the semiconductor body.

The power semiconductor device including a sub-divided collector region and a sub-divided cathode region allows for technical benefits. By providing a structured collector region of the IGBT area including low p-doped and high p-doped collector sub-regions, the p− regions (p+/p−) may be arranged for limiting the hole injection efficiency at light-load (low energy loss during turn-off, i.e. low Eoff), while at high-load up to short-circuit condition provide an increased hole injection for reducing the surge voltage and counteracting unstable filamentation that may lead to short circuit destruction within the pulse. By providing a structured cathode in the diode area including the cathode region and the auxiliary region, a reduction of plasma concentration in the diode drift region may be achieved. This may allow for reducing the reverse recovery charge. The structured cathode design may further allow for improving the trade-off between contact resistance to a metal collector contact and injection efficiency. Collector formation, e.g. by ion implantation, may have a double-function caused by the possibility to also control the softness of the diode by this process feature, for example.

For example, the power semiconductor device may further include an interface region arranged between the collector region and at least one of the cathode region or the auxiliary region. One lateral end of the interface region may adjoin to the collector region and the other lateral end of the interface region may adjoin to the at least one of the cathode region or the auxiliary region. The interface region may provide for a lateral separation between different chip functionalities, e.g. diode functionality and IGBT functionality of a RC-IGBT. For example, the interface region may allow for an electrical decoupling of areas with different functionalities, e.g. diode area and IGBT area of a RC-IGBT. For example, the interface region may differ from adjoining parts of the collector region and the at least one of the cathode region or the auxiliary region by one or more of, a maximum or minimum doping concentration, a lateral doping concentration profile, a vertical doping concentration profile, and arrangement pattern and/or dimensions of doped sub-regions. For example, the interface region may be an area where on the first main surface, e.g. front surface, no IGBT emitter may be present, but only an “anode” effect. The anode efficiency may be less or equal to that of the actual diode region. At the second main surface, e.g. back surface, no cathode (i.e. no n-type implant) may be present but only an IGBT collector of injection efficiency defined by a doping level anywhere between the minimum and the maximum doping level of the collector region.

For example, an extent of the interface region along the first lateral direction ranges from 1 μm to 650 μm, or from 1 μm to 100 μm. The extent of the interface region along the first lateral direction may increase with increasing voltage blocking class of the power semiconductor device. For interface regions surrounding the diode area or the IGBT area, e.g. when separate diode areas are integrated or embedded into an IGBT area or vice versa, the lateral extent may be a width of a closed traverse surrounding the diode or IGBT area, for example. In this case, the above range for the extent along the first lateral direction may likewise apply to other lateral directions. For example, when the interface region is shaped, in a top view, as a closed traverse surrounding, for example, a rectangular diode area integrated or embedded into an IGBT area, the above range may apply to an extent of the interface region along the first lateral direction with respect to opposite two sides of the closed traverse, and may likewise apply to an extent of the interface region along a second lateral direction with respect to the other opposite two sides of the closed traverse, wherein the second lateral is perpendicular to the first lateral direction. This relationship may likewise apply to other geometries, e.g. interface regions shaped, in a top view, as a closed traverse surrounding, for example, a polygonal or circular or elliptical diode area integrated into an IGBT area. For example, the lateral extent of the interface region along the first lateral direction may be limited by a thickness of the semiconductor substrate, e.g. a vertical distance between the first main surface and the second main surface.

For example, the first collector sub-region may have a larger maximum doping concentration or an equal maximum doping concentration as the interface region.

For example, the interface region may be of the second conductivity type, i.e. the conductivity of the collector region, and a maximum doping concentration of the interface region may be equal to a maximum doping concentration of the auxiliary region. The interface region may have a same vertical doping concentration profile as the auxiliary region, for example.

For example, a doping concentration of the interface region may vary along the first lateral direction. The variation along the first lateral direction may refer to a vertical reference level inside the interface region that has a vertical distance to the second main surface, for example. The doping concentration along the first lateral direction may steadily vary along at least a part of the extent of the interface region along the first lateral direction. For example, at a reference location at the vertical level inside the interface region, the doping concentration profile along the first lateral direction may have a positive or negative gradient, and a gradient of the doping concentration profile along a second lateral direction may be zero, wherein the second lateral direction may be perpendicular to the first lateral direction. In other words, while the doping concentration of the interface region may vary along the first lateral direction at the reference location, it may be constant along the second lateral direction, for example. The gradient of the doping concentration of the interface region along the first lateral direction may be set, for example, by layout of an ion implantation mask for introducing dopants for the interface region into the semiconductor substrate via the second main surface.

For example, the doping concentration of the interface region may vary along the first lateral direction between the doping concentration of the first collector sub-region and the doping concentration of the second collector sub-region. For example, ion implantation processes for forming the first and second collector sub-regions may be used for forming at least part of the interface region. The variation along the first lateral direction may refer to a vertical reference level inside the interface region that has a vertical distance to the second main surface, for example.

For example, a doping concentration profile of the interface region along the first lateral direction may have a peak at a center of the lateral extent of the interface region along the first lateral direction. The doping concentration profile of the interface region may steadily decrease up to or close to the IGBT area along the first lateral direction starting from the peak, for example.

For example, the doping concentration of the auxiliary region may vary along the first lateral direction. The variation along the first lateral direction may refer to a vertical reference level inside the auxiliary region that has a vertical distance to the second main surface, for example. The doping concentration along the first lateral direction may steadily vary along at least a part of the extent of the auxiliary region along the first lateral direction. For example, at a reference location at the vertical level inside the auxiliary region, the doping concentration profile along the first lateral direction may have a positive or negative gradient, and a gradient of the doping concentration profile along a second lateral direction may be zero, wherein the second lateral direction may be perpendicular to the first lateral direction. In other words, while the doping concentration of the auxiliary region may vary along the first lateral direction at the reference location, it may be constant along the second lateral direction, for example. The gradient of the doping concentration of the auxiliary region along the first lateral direction may be set by layout of an ion implantation mask for introducing dopants for the auxiliary region into the semiconductor substrate via the second main surface.

For example, the doping concentration of the auxiliary region may vary along the first lateral direction between the doping concentration of the first collector sub-region and the doping concentration of the second collector sub-region. For example, ion implantation processes for forming the first and second collector sub-regions may be used for forming at least part of the auxiliary region.

For example, a doping concentration profile of the auxiliary region along the first lateral direction may have a peak at a center of a lateral extent of the auxiliary region along the first lateral direction. The doping concentration profile of the auxiliary region may steadily decrease up to or close to the cathode area along the first lateral direction starting from the peak, for example. In some other examples, the doping concentration profile of the auxiliary region may have a minimum at a center of a lateral extent of the auxiliary region along the first lateral direction. In this case, the doping concentration profile of the auxiliary region may steadily increase up to or close to the cathode area along the first lateral direction starting from the minimum, for example.

For example, a shape of the auxiliary region in a top view may be at least one of a stripe, a grid, or a closed traverse. The closed traverse may define a border or an edge of a polygon, e.g. a rectangle, a hexagon, an octagon, or a circle, or an ellipse. For stripe-shaped auxiliary regions, a plurality of the stripe-shaped auxiliary regions may be arranged parallel to each other with stripe-shaped cathode regions arranged between neighbouring two of the stripe-shaped auxiliary regions. For auxiliary regions shaped as a closed traverse, auxiliary regions in the shape of a closed traverse and cathode regions in the shape of a closed traverse may be interlaced alternately, for example. In this case, the further inside an auxiliary region or a cathode region is arranged, the smaller are their lateral dimensions of the closed traverse. The exemplary layouts of the auxiliary region and cathode region of the diode area described above likewise apply to the first and second collector sub-regions of the IGBT area.

For example, a pitch of arrangement of auxiliary regions may vary along the first lateral dimension. The pitch of arrangement of auxiliary regions may differ between the first lateral direction and a second lateral direction that is perpendicular to the first lateral direction. For example, a varying pitch may be set by varying a minimum lateral extent, e.g. a width, of the auxiliary regions and/or the cathode regions. For example, when forming stripe-shaped auxiliary regions and stripe-shaped cathode regions, a width of the auxiliary regions may vary, e.g. increase or decrease, along the first lateral direction. In addition, or as an alternative, a width of the cathode regions may vary, e.g. increase or decrease, along the first lateral direction. Varying pitches may likewise be set for other layouts of the auxiliary regions and cathode regions. For example, varying pitches may also be set for auxiliary regions and cathode regions shaped as a closed traverse. For example, the pitch of arrangement of auxiliary regions may differ between the first and second lateral directions when arranging the auxiliary regions as grid lines with cathode regions being placed in the openings of the grid. In this case, a lateral extent of the cathode regions along the first lateral direction may differ from a lateral extent of the cathode regions along the second lateral direction. For example, the pitch of arrangement of cathode regions may differ between the first and second lateral directions when arranging the cathode regions as grid lines with auxiliary regions being placed in the openings of the grid. In this case, a lateral extent of the auxiliary regions along the first lateral direction differs from a lateral extent of the auxiliary regions along the second lateral direction. The exemplary layouts of the auxiliary regions and cathode regions having a different pitch of arrangement in the diode area described above likewise apply to the first and second collector sub-regions in the IGBT area.

For example, the power semiconductor device may further include an edge termination area at least partly surrounding the diode area and the IGBT area. A second interface region may be arranged between the edge termination area and at least one of the cathode region or the auxiliary region. One lateral end of the second interface region may adjoin to the edge termination area and the other lateral end of the second interface region may adjoin to the at least one of the cathode region or the auxiliary region. Details described with respect to the interface region in the examples above or below likewise apply to the second interface region.

Another example of the present disclosure relates to another power semiconductor device. The power semiconductor device includes a semiconductor substrate having a first main surface and a second main surface arranged opposite to each other. The semiconductor substrate may include a diode area comprising a diode. The diode area may include a cathode region of a first conductivity type at the second main surface of the semiconductor substrate. The diode area may further include an auxiliary region of a second conductivity type at the second main surface of the semiconductor substrate. The cathode region may adjoin to the auxiliary region along a first lateral direction. The doping concentration of the auxiliary region may vary along the first lateral direction. Details described above and below with respect to the cathode region or the auxiliary region likewise apply.

Details with respect to structure, or function, or technical benefit of features described above with respect to a power semiconductor device such as a power semiconductor RC-IGBT or a power semiconductor diode, likewise apply to the exemplary methods described herein. Processing the semiconductor substrate may comprise one or more optional additional features corresponding to one or more aspects mentioned in connection with the proposed concept or one or more examples described above or below.

An example of the present disclosure relates to a method of manufacturing a power semiconductor device. The method includes providing a semiconductor substrate having a first main surface and a second main surface arranged opposite to each other. The method may further include forming an IGBT in an insulated gate bipolar transistor area, IGBT area. The method may further include forming a diode in a diode area. Forming the diode in the diode area may include forming a cathode region of a first conductivity type at the second main surface of the semiconductor substrate, and an auxiliary region of a second conductivity type at the second main surface of the semiconductor substrate. The cathode region may adjoin to the auxiliary region along a first lateral direction. Forming the IGBT in the IGBT area may include forming a collector region of the second conductivity type at the second main surface of the semiconductor substrate. The collector region may include a first collector sub-region and a second collector sub-region adjoining to each other along the first lateral direction. The first collector sub-region may have a larger maximum doping concentration than the second collector sub-region.

For example, forming the cathode region may include forming a cathode mask, e.g. hard mask or resist mask, over the second main surface of the semiconductor substrate. The cathode mask may include a mask opening directly over the cathode region. The cathode mask may further include a mask region directly over the auxiliary region. The mask region over the auxiliary region may allow for hindering dopants from being introduced into the auxiliary region when introducing dopants into the cathode region via the openings in the cathode mask. The dopants may be introduced by one or more ion implantation processes, for example. The cathode mask may further include a mask region directly over the interface region and/or the second interface region for hindering dopants from being introduced into the interface region and/or the second interface region when introducing dopants into the cathode region via the openings in the cathode mask.

For example, forming the collector region may include forming a collector mask, e.g. hard mask or resist mask, over the second main surface of the semiconductor substrate. The collector mask may include a mask opening directly over the first collector sub-region. The collector mask may further include a mask region directly over the second collector sub-region. The mask region over the second collector sub-region may allow for hindering dopants from being introduced into the second collector sub-region when introducing dopants into the first collector sub-region via the openings in the collector mask. The dopants may be introduced by one or more ion implantation processes, for example. The collector mask may further include a mask region directly over the interface region and/or the second interface region for hindering dopants from being introduced into the interface region and/or the second interface region when introducing dopants into the first collector sub-region via the openings in the collector mask.

For example, the collector mask may further include a mask opening directly over the auxiliary region in the diode area. When only partly masking the auxiliary region, a lateral doping concentration profile of the auxiliary region may vary, e.g. along the first lateral direction.

For example, the method may further include introducing dopants of the second conductivity type through the second main surface into the semiconductor substrate by an unmasked ion implantation process. Dopants of the second collector sub-region may be introduced into the semiconductor substrate by the unmasked ion implantation process, for example. Likewise, dopants of the interface region may be introduced into the semiconductor substrate by the unmasked ion implantation process, for example. Also dopants of the auxiliary region may be introduced into the semiconductor substrate by the unmasked ion implantation process, for example. This may allow for a cost-effective formation of semiconductor regions having different device functionalities.

For example, an ion implantation dose of the dopants of the second conductivity type may range from 1×10¹² cm⁻² to 5×10¹⁵ cm⁻².

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps, or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation, or step may include or may be broken into multiple sub-acts, -functions, -processes, -operations or -steps, respectively. Such sub acts may be included and part of the disclosure of this single act unless explicitly excluded.

The examples and features described above and below may be combined. Functional and structural details (e.g. materials, dimensions) described with respect to the examples above shall likewise apply to the examples illustrated in the figures and described further below.

More details and aspects are mentioned in connection with the examples described above or below. Processing a semiconductor substrate, e.g. a wafer, may comprise one or more optional additional features corresponding to one or more aspects mentioned in connection with the proposed concept or one or more examples described above or below.

The doping level of doped regions illustrated in the figures may be set in relation to one another by adding “+” or “−” to the doping type, e.g. p⁺-doped or p⁻-doped. A p⁺-doped region has a higher doping level than a p-doped region, and a p-doped region has a higher doping level than a p-doped region. The same applies to n-type doping levels.

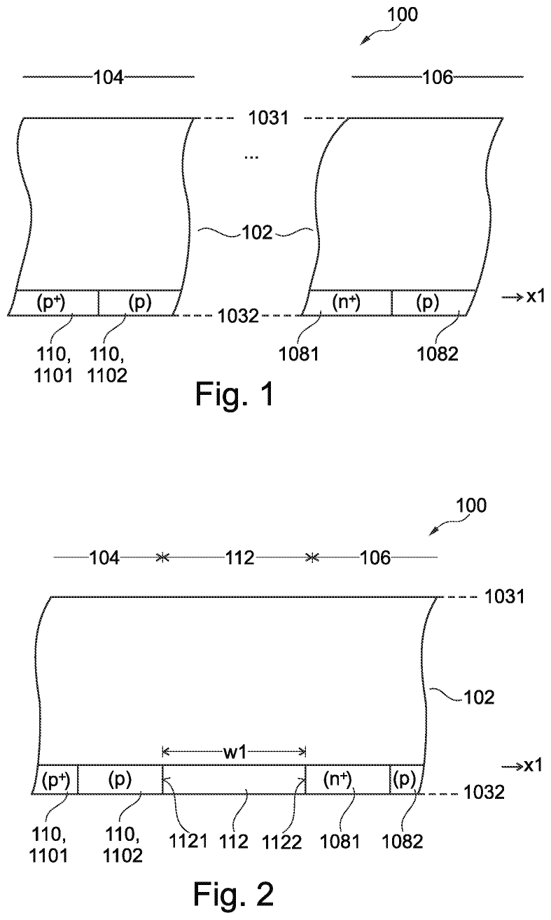

FIG. 1 schematically and exemplarily shows a partial cross-sectional view of an example of a power semiconductor device 100, e.g. a power RC-IGBT. A semiconductor substrate 102 of the power semiconductor device 100 has a first main surface 1031 and a second main surface 1032 arranged opposite to the first main surface 1031.

In the semiconductor substrate 102, an IGBT is formed in an IGBT area 104, and a diode is formed in the diode area 106.

In the diode area 106, an n⁺-doped cathode region 1081 is formed at the second main surface 1032 of the semiconductor substrate 102. A p-doped auxiliary region 1082 is formed at the second main surface 1032 of the semiconductor substrate 102. The cathode region 1081 adjoins to the auxiliary region 1082 along a first lateral direction x1.

In the IGBT area 104, a collector region 110 of the second conductivity type is formed at the second main surface 1032 of the semiconductor substrate 102 The collector region 110 includes a p+-doped first collector sub-region 1101 and a p-doped second collector sub-region 1102 adjoining to each other along the first lateral direction x1. The first collector sub-region 1101 has a larger maximum doping concentration than the second collector sub-region 1102.

Exemplary details described above with respect to a power semiconductor device may be applied to the power semiconductor device 100 illustrated in FIG. 1.

FIG. 2 schematically and exemplarily shows a partial cross-sectional view of another example of a power semiconductor device 100, e.g. a power RC-IGBT.

An interface region 112 of the power semiconductor device 100 is arranged between the p-doped second collector sub-region 1102 and the n⁺-doped cathode region 1081. A lateral end 1121, e.g. side face, of the interface region 112 adjoins to the p-doped second collector sub-region 1102 and the other lateral end 1122, e.g. side face, of the interface region 112 adjoins to the n⁺-doped cathode region 1081. In other cross-sectional views of the power semiconductor device 100, the lateral end 1121 of the interface region 112 may adjoin to the p⁺-doped first collector sub-region 1101 and the other lateral end 1122 side face, of the interface region 112 may adjoin to the n⁺-doped cathode region 1081. Likewise, the lateral end 1121 of the interface region 112 may adjoin to the p⁺-doped first collector sub-region 1101 and the other lateral end 1122 of the interface region 112 may adjoin to the p-doped auxiliary region 1082. In yet another cross-sectional view of the power semiconductor device 100, the lateral end 1121 of the interface region 112 may adjoin to the p-doped second collector sub-region 1102 and the other lateral end 1122 of the interface region 112 may adjoin to the p-doped auxiliary region 1082. For example, an extent w1 of the interface region 112 along the first lateral direction x1 may range from 1 μm to 650 μm, e.g. depending on blocking voltage requirements of the power semiconductor device 100.

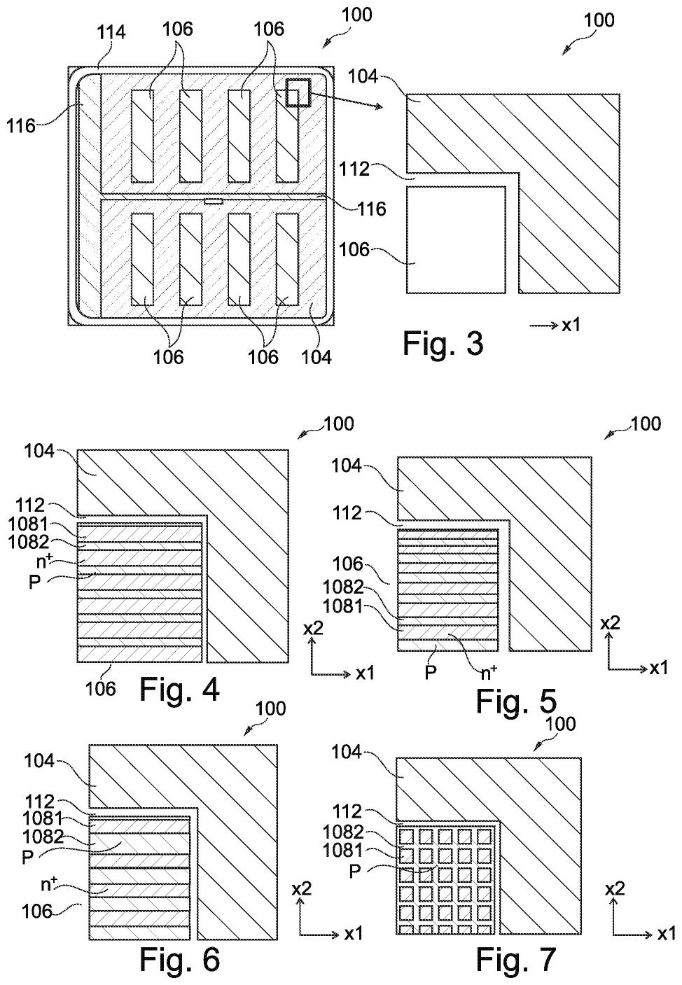

The schematic top views of FIG. 3 illustrate an exemplary layout of a power semiconductor device 100 including diode areas 106 embedded into the IGBT area 104. An edge termination area 114 surrounds the IGBT area 104 and a sense and control pad or runner area 116. More exemplary details with respect to the diode area 106, the interface region 112, or the IGBT area 104 illustrated in the magnified sector of the right part of FIG. 3 will be described with reference to additional figures below.

Referring to the schematic top view of FIG. 4, the power semiconductor device 100 includes stripe-shaped n+-doped cathode regions 1081 and p-doped auxiliary regions 1082. In some examples, the p-doped auxiliary regions 1082 may be formed by p⁺/p⁻-doped sub-regions or may have a laterally varying p-doping concentration profile. A pitch of arrangement of the stripe-shaped n+-doped cathode regions 1081 is constant along a second lateral direction x2. Likewise, a pitch of arrangement of the stripe-shaped p-doped auxiliary regions 1082 is constant along the second lateral direction x2. In the examples illustrated in the schematic top views of FIGS. 5 and 6, the pitch of arrangement of the stripe-shaped n⁺-doped cathode regions 1081 and the stripe-shaped p-doped auxiliary regions 1082 varies, e.g. increases, along the second lateral direction x2 by varying a minimum lateral extent, e.g. a width, of the stripe-shaped n⁺-doped cathode regions 1081 (see FIG. 5) or of the stripe-shaped p-doped auxiliary regions 1082 (see FIG. 6).

Referring to the schematic top view of FIG. 7, the p-doped auxiliary regions 1082 in the diode area 106 may be arranged as grid lines forming a grid, wherein the n⁺-doped cathode regions 1081 fill the openings of the grid. A pitch of arrangement of the n⁺-doped cathode regions 1081 along the first and second lateral directions x1, x2 may differ by setting different lateral extents of the n⁺-doped cathode regions 1081 along the first and second lateral directions x1, x2, for example, or, in addition or as an alternative, by setting different widths for the grid lines along the first and second lateral directions x1, x2. A shape of the grid may differ from a rectangular shape, e.g. be hexagonal or octahedral.

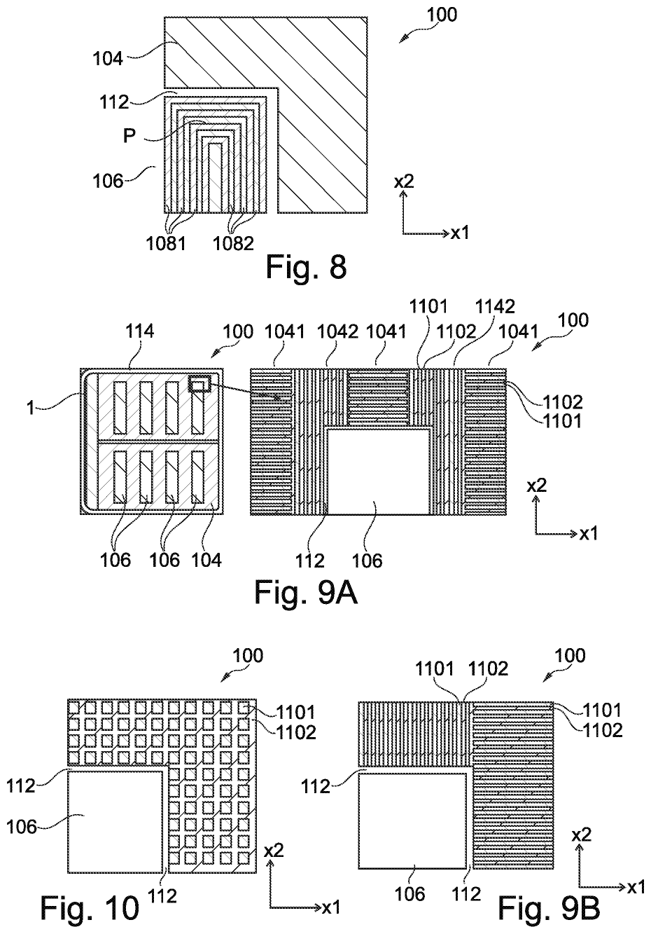

The schematic top view of FIG. 8 is a partial view for illustrating an example of interlaced and closed-traverse p-doped auxiliary regions 1082 and n⁺-doped cathode regions 1081 in the diode area 106. For illustrative purposes, only a section of the closed-traverse p-doped auxiliary regions 1082 and n⁺-doped cathode regions 1081 is illustrated in the top view. By varying a width of the p-doped auxiliary regions 1082 and/or n⁺-doped cathode regions 1081, a pitch of arrangement of the p-doped auxiliary regions 1082 and the n⁺-doped cathode regions 1081 may be varied.

The schematic top views of FIG. 9A illustrate an exemplary layout of the power semiconductor device 100 including diode areas 106 embedded into the IGBT area 104. More exemplary details with respect to the IGBT area 104 are illustrated in the magnified sector of the right part of FIG. 9A. In the IGBT area 104, first and second IGBT sub-areas 1041, 1042 are arranged. In each of the first and second IGBT sub-areas 1041, 1042, stripe-shaped first and second collector sub-regions 1101, 1102 extend in parallel to each other. In the first IGBT sub-area 1041, the stripe-shaped first and second collector sub-regions 1101, 1102 extend in parallel to each other along the first lateral direction x1. In the second IGBT sub-area 1042, the stripe-shaped first and second collector sub-regions 1101, 1102 extend in parallel to each other along the second lateral direction x2. When varying a direction of extension of the stripe-shaped first and second collector sub-regions 1101, 1102 between the first lateral direction x1 in the first IGBT sub-area 1041 and the second lateral direction x2 in the second IGBT sub-area 1042, a homogeneity of surface coverage with differently p-doped collector sub-regions, e.g. an averaged collector p-doping over a certain area, may be improved. This may allow for counteracting undesired local enhancement or decrease of hole injection, for example. Another exemplary layout having first and second IGBT sub-areas 1041, 1042 is illustrated in the schematic top view of FIG. 9B. The layout of FIG. 9B allows for a more balanced transition between an edge of the interface region 112 and the collector sub-regions 1101, 1102 because no stripe-shaped collector sub-region extends in parallel to the edge of the interface region 112. This may allow for a further reduction of the diode switching losses by reducing addition hole injection from the vicinity of the diode region compared with FIG. 9A that may have a larger hole injection caused by a higher p-doped, e.g. p+-doped, stripe-shaped collector sub-region extending in parallel to the edge of the transition region 112.

Referring to the schematic top view of FIG. 10, the p-doped second collector sub-regions 1102 in the IGBT area 104 are arranged as grid lines forming a grid. The p⁺-doped first collector sub-regions 1101 fill the openings of the grid. A pitch of arrangement of the p⁺-doped first collector sub-regions 1101 along the first and second directions x1, x2 may differ by setting different lateral extents for the p⁺-doped first collector sub-regions 1101 along the first and second directions x1, x2, for example, or, in addition or as an alternative, by setting different widths for the grid lines along the first and second lateral directions x1, x2. A shape of the grid may differ from a rectangular shape, e.g. be hexagonal or octahedral.

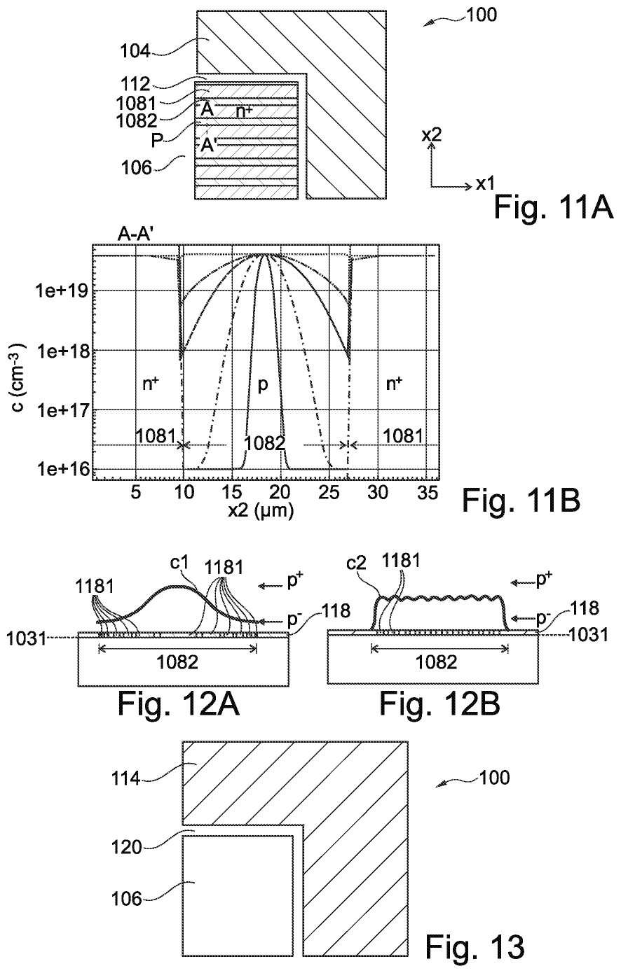

The schematic top view of FIG. 11A and the schematic graph of FIG. 11B illustrate examples of varying doping concentrations c in the auxiliary region 1082 of the diode area 106. The exemplary doping concentration profiles of FIG. 11B have a peak at a center of a lateral extent of the auxiliary region 1082 along the second lateral direction x2. For example, the doping concentration profile may vary between the doping levels of the p-doped second collector sub-region 1102 and the p+-doped first collector sub-region 1101 in the IGBT area 104. The doping concentration profiles may be set in view of specific electric characteristics, e.g. diode overvoltage.

The schematic views of FIGS. 12A and 12B illustrate exemplary mask patterns for setting varying doping concentration profiles in the auxiliary region 1082. A mask 118, e.g. an ion implantation hard mask or resist mask, over the auxiliary region 1082 includes mask openings 1181 over the auxiliary region 1082 for allowing dopants to be introduced into the semiconductor substrate. When decreasing a width of the mask openings towards lateral ends of the auxiliary region 1082, a doping concentration peak may be located in a center of a lateral extent of the auxiliary region 1082 as illustrated by curve c1 in FIG. 12A. When consecutively arranging mask openings 1181 and masked regions having constant lateral widths, a maximum doping concentration level in the auxiliary region may be adjusted as illustrated by curve c2 in FIG. 12B, for example. The final doping concentration profile may deviate from an as-implanted profile due to out-diffusion of the dopants caused by a thermal budget for electrically activating the dopants, e.g. by laser thermal annealing (LTA), or any other subsequent processes involving thermal treatment.

The schematic top view of FIG. 13 illustrates another exemplary part of a power semiconductor device 100 including an edge termination area 114 at least partly surrounding the diode area 106. A second interface region 120 is arranged between the edge termination area 114 and at least one of the cathode region or the auxiliary region of the diode area 106. The power semiconductor device illustrated in FIG. 13 may be a power diode or the diode area of a RC-IGBT, for example.

Profiles and processes of varying doping concentration profile in the auxiliary region 1082 as described with reference to FIGS. 11A, 11B, 12A, 12B may likewise be applied to the doping concentration profile in the interface region 112, the second interface region 120 and/or the p-doped second collector region 1102, for example. Profiles and processes of varying doping concentration profile in the auxiliary region 1082 as described with reference to FIGS. 11A, 11B, 12A, 12B may likewise be applied to a power semiconductor diode without any IGBT area, e.g. a stand-alone power semiconductor diode including the auxiliary region and the cathode region in the diode area.

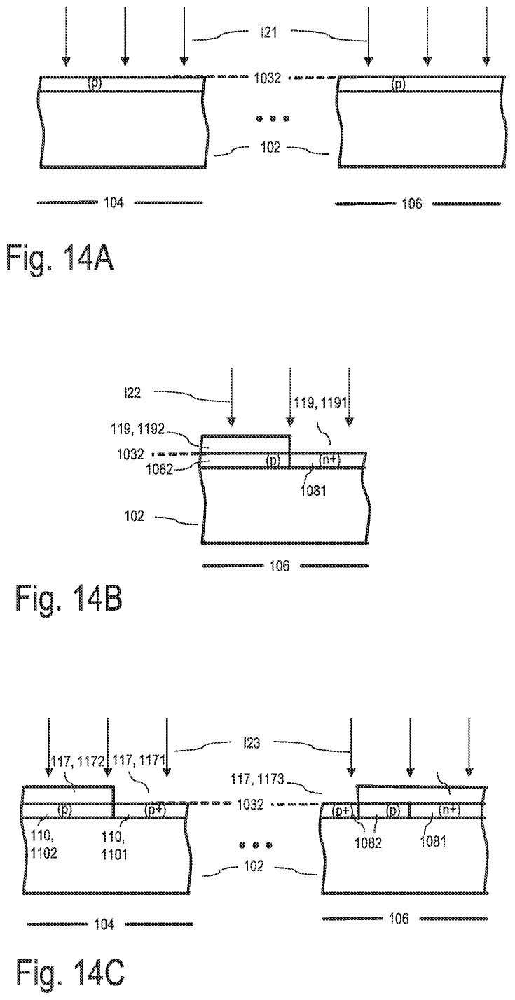

Exemplary process features of manufacturing the power semiconductor device 100 are illustrated in FIGS. 14A to 14C.

Referring to the schematic cross-sectional view of FIG. 14A, p-type dopants are introduced through the second main surface 1032 into the semiconductor substrate 102 by an unmasked ion implantation process 121. The p-type dopants may define the second collector region 1102, and/or at least part of the auxiliary region 1082, and/or at least part of the interface region 112, and/or at least part of the second interface region 120.

Referring to the schematic cross-sectional view of FIG. 14B, the cathode region 1081 may be formed by patterning a cathode mask 119 over the second main surface 1032 of the semiconductor substrate 102. The cathode mask 119 includes a mask opening 1191 directly over the cathode region 1081 and a mask region 1192 directly over the auxiliary region 1082. The cathode region 1081 is defined by introducing n-type dopants through the mask opening 1191 and through the second main surface 1032 into the semiconductor substrate 102 by a masked ion implantation process 122.

Referring to the schematic cross-sectional view of FIG. 14C, the collector region 110 may be formed by patterning a collector mask 117 over the second main surface 1032 of the semiconductor substrate 102. The collector mask 117 includes a mask opening 1171 directly over the first collector sub-region 1101 and a mask region 1172 directly over the second collector sub-region 1102. The collector mask 117 may further include a mask opening 1173 directly over the auxiliary region 1082 in the diode area 106. The first collector sub-region 1101 is defined by introducing p-type dopants through the mask opening 1171 and through the second main surface 1032 into the semiconductor substrate 102 by a masked ion implantation process 123. Likewise, p-type dopants may be introduced through the mask opening 1173 directly over the auxiliary region 1082 in the diode area 106 by the masked ion implantation process 123 for defining a doping concentration profile in the auxiliary region 1082 that varies along a lateral direction.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor device, comprising:
a semiconductor substrate having a first main surface and a second main surface arranged opposite to each other, the semiconductor substrate comprising an insulated gate bipolar transistor (IGBT) area comprising an IGBT, and a diode area comprising a diode,
wherein the diode area comprises a cathode region of a first conductivity type at the second main surface of the semiconductor substrate, and an auxiliary region of a second conductivity type at the second main surface of the semiconductor substrate,
wherein the cathode region adjoins to the auxiliary region along a first lateral direction,
wherein the IGBT area comprises a collector region of the second conductivity type at the second main surface of the semiconductor substrate, the collector region comprising a first collector sub-region and a second collector sub-region adjoining to each other along the first lateral direction, the first collector sub-region having a larger maximum doping concentration than the second collector sub-region.

2. The power semiconductor device of claim 1, further comprising an interface region arranged between the collector region and at least one of the cathode region or the auxiliary region, one lateral end of the interface region adjoining to the collector region and the other lateral end of the interface region adjoining to the at least one of the cathode region or the auxiliary region.

3. The power semiconductor device of claim 2, wherein an extent of the interface region along the first lateral direction ranges from 1 μm to 650 μm.

4. The power semiconductor device of claim 2, wherein the first collector sub-region has a larger maximum doping concentration or an equal maximum doping concentration as the interface region.

5. The power semiconductor device of claim 2, wherein the interface region has the second conductivity type, and wherein a maximum doping concentration of the interface region is equal to a maximum doping concentration of the auxiliary region.

6. The power semiconductor device of claim 2, wherein a doping concentration of the interface region varies along the first lateral direction.

7. The power semiconductor device of claim 6, wherein the doping concentration of the interface region varies along the first lateral direction between the doping concentration of the first collector sub-region and the doping concentration of the second collector sub-region.

8. The power semiconductor device of claim 1, wherein the doping concentration of the auxiliary region varies along the first lateral direction.

9. The power semiconductor device of claim 1, wherein the doping concentration of the auxiliary region varies along the first lateral direction between the doping concentration of the first collector sub-region and the doping concentration of the second collector sub-region.

10. The power semiconductor device of claim 1, wherein a doping concentration profile of the auxiliary region along the first lateral direction has a peak at a center of a lateral extent of the auxiliary region along the first lateral direction.

11. The power semiconductor device of claim 1, wherein a shape of the auxiliary region in a top view is at least one of a stripe, a grid, or closed traverse.

12. The power semiconductor device of claim 1, wherein a pitch of arrangement of auxiliary regions varies along the first lateral dimension, or differs between the first lateral direction and a second lateral direction that is perpendicular to the first lateral direction.

13. The power semiconductor device of claim 1, further comprising:
an edge termination area at least partly surrounding the diode area and the IGBT area; and
a second interface region arranged between the edge termination area and at least one of the cathode region or the auxiliary region,
wherein one lateral end of the second interface region adjoins to the edge termination area and the other lateral end of the second interface region adjoins to at least one of the cathode region or the auxiliary region.

14. A power semiconductor device, comprising:
a semiconductor substrate having a first main surface and a second main surface arranged opposite to each other, the semiconductor substrate comprising a diode area comprising a diode,
wherein the diode area comprises a cathode region of a first conductivity type at the second main surface of the semiconductor substrate, and an auxiliary region of a second conductivity type at the second main surface of the semiconductor substrate,
wherein the cathode region adjoins to the auxiliary region along a first lateral direction,
wherein a doping concentration of the auxiliary region varies along the first lateral direction.

15. A method of manufacturing a power semiconductor device, the method comprising:
providing a semiconductor substrate having a first main surface and a second main surface arranged opposite to each other; and
forming an insulated gate bipolar transistor (IGBT) in an IGBT area, and a diode in a diode area,
wherein forming the diode in the diode area comprises forming a cathode region of a first conductivity type at the second main surface of the semiconductor substrate, and an auxiliary region of a second conductivity type at the second main surface of the semiconductor substrate, wherein the cathode region adjoins to the auxiliary region along a first lateral direction,
wherein forming the IGBT in the IGBT area comprises forming a collector region of the second conductivity type at the second main surface of the semiconductor substrate, the collector region comprising a first collector sub-region and a second collector sub-region adjoining to each other along the first lateral direction, the first collector sub-region having a larger maximum doping concentration than the second collector sub-region.

16. The method of claim 15, wherein forming the cathode region comprises forming a cathode mask over the second main surface of the semiconductor substrate, the cathode mask comprising a mask opening directly over the cathode region and a mask region directly over the auxiliary region.

17. The method of claim 15, wherein forming the collector region comprises forming a collector mask over the second main surface of the semiconductor substrate, the collector mask comprising a mask opening directly over the first collector sub-region and a mask region directly over the second collector sub-region.

18. The method of claim 17, wherein the collector mask further comprises a mask opening directly over the auxiliary region in the diode area.

19. The method of claim 17, further comprising introducing dopants of the second conductivity type through the second main surface into the semiconductor substrate by an unmasked ion implantation process.

20. The method of claim 19, wherein an ion implantation dose of the dopants of the second conductivity type ranges from 1×10¹² cm⁻² to 5×10¹⁵ cm⁻².
